(19) United States
(12) Patent Application Publication
(10) Pub. No.: US 2014/0239954 A1
(43) Pub. Date: Aug. 28, 2014

(54) Method and System for Generating Magnetic Field Gradients for an NMR Imaging Machine

(71) Applicant: Guy G. Aubert, Poitiers (FR)

(72) Inventor: Guy G. Aubert, Poitiers (FR)

(73) Assignee: Commissariat A L'Energie Atomique Et Aux Energies Alternatives, Paris (FR)

(21) Appl. No.: 14/236,476

(22) PCT Filed: Jul. 24, 2012
(86) PCT No.: PCT/FR2012/051756

§ 371 Date: May 12, 2014

(30) Foreign Application Priority Data
Aug. 1, 2011 (FR) 1157029

(51) Int. Cl. G01R 33/341; G01R 33/34

(52) U.S. Cl. CPC G01R 33/341; G01R 33/34007
USPC 324/322; 29/593

(57) ABSTRACT

Disclosed is a gradient generator system arranged around a volume of interest of axis Oz. The system includes z-gradient coils of axis Oz; z-gradient tubes of axes parallel to the axis Oz including coils arranged in a ring outside the z-gradient coils; x-gradient coils and y-gradient coils of saddle shape arranged around the z-gradient coils; and x and y-gradient tubes of axes parallel to the axis Oz and situated in a ring outside the z-gradient coils, being interposed between the z-gradient tubes, with each of the x and y gradient tubes including coils.

### FIELD OF THE INVENTION

The present invention relates to a method and to a system for generating magnetic field gradients in order to create a magnetic field gradient in a volume of interest in a nuclear magnetic resonance (NMR) or a magnetic resonance imaging (MRI) machine having a superconductive magnet.

The invention also relates to a nuclear magnetic resonance imaging machine with improved gradients.

### PRIOR ART

A nuclear magnetic resonance imaging appliance essentially comprises three types of coil or the equivalent.

Coils of a first type, which can be replaced by a permanent magnet, serve to create a main magnetic field B₀ that is intense and uniform in a predetermined volume of interest. The term “intense” magnetic field is used to mean a magnetic field of not less than 0.5 teslas (T), and preferably greater than or equal to 1 T, and that in certain embodiments may exceed 10 T, for NMR or MRI applications. By way of example, the first coil may be constituted by a superconductive main magnetization coil placed in a cryostat.

Coils of a second type, referred to as radiofrequency coils, serve to cause a body or article under examination that is placed under the influence of the main field from the first coils or from the permanent magnets to be subjected to radiofrequency excitation sequences, and they also serve to measure radiofrequency signals re-emitted in return by particles of the body or article under examination. The radiofrequency response is a volume response: all of the particles in a region of the body subjected to examination emit their radiofrequency responses simultaneously. To create an image, it is necessary to distinguish between these responses.

Coils of a third type, referred to as gradient coils, serve specifically to superpose an additional magnetic field on the intense main field B₀. The values of these components are a function of three-dimensional coordinates of the locations where they are applied. Conventionally, this distinction is organized along three orthogonal axes X, Y, and Z. By convention, the Z axis is generally taken to be colinear with the intense field B₀ created by the coils of the first type or by the permanent magnet. Each location in three-dimensional space may be encoded by means of a different field value, and in the re-emitted signal use is made of the resulting modifications for the purpose of creating the image.

Thus, during the application of radiofrequency excitation sequences, image acquisition requires joint excitation of field gradient sequences that are pulsed.

Document EP-A-0 221 810 summarizes MRI and indicates how to calculate gradients that are as linear as possible, while taking account of given available space, in particular for X or Y gradient coils referred to as saddle coils that constitute conventional gradient coils.

In general manner, a problem to be solved consists in finding gradient coils for a given location that produce a gradient that is sufficiently strong and uniform and that presents self-inductance that is low. These requirements are contradictory. In order to obtain high quality NMR imaging, it is appropriate for the real field gradients to be uniform, i.e. to comply to within given tolerance with an ideal theoretical distribution that is it desired to impose. In order to increase the uniformity of the gradients that are produced, the gradient coils need to be as large as possible, however for reasons of available space and power, it is also appropriate to avoid excessively increasing the size of these coils.

Furthermore, as stated in document WO 89/03031, protective screens are the seat of eddy currents and they require special arrangements to be provided in the gradient coils in order to tend to reduce the influence of these eddy currents which tend to oppose the establishment of the additional magnetic field of desired gradient.

In particular for the purpose of reducing the noise created by gradient coils designed for tunnel type NMR machines creating an intense orienting field, document WO 2005/029110 proposes using the annular space available for installing tubes of axes parallel to the main field and in which circular solenoidal coils are engaged in order to take the place of conventional saddle-shaped gradient coils for providing the gradient. The tubes may be contiguous with one another so as to form a sheet of tubes.

Placing circular solenoidal coils in tubes generally makes it possible to achieve the expected results of producing gradients of great intensity, because of improved possibilities for cooling, because of linearity constraints imposed by specifications, because of reduced acoustic noise, and to a certain extent because of eddy currents being limited.

Nevertheless, under certain circumstances those eddy currents can remain troublesome, in particular by leading to excessive heating of the cryostat of the main magnet, thereby increasing the consumption of cryogenic fluid, and interposing screens between the gradient generators and the cryostat contributes to diminishing the effectiveness of the gradients, even though it does make it possible to reduce the electric fields produced outwardly by the gradient generators.

In order to remedy those drawbacks, proposals are made in document WO 2007/048983 to make a first set of solenoidal gradient coils placed in tubes arranged in a first cylindrical annular space, and a second set of compensation solenoidal gradient coils placed in tubes arranged in a second cylindrical annular space coaxial with the first cylindrical annular space and situated between an outer cryogenic enclosure and the first cylindrical annular space, with the flow directions of the pulse currents being opposite in the coils of the second set relative to the flow direction in the coils of the first set.

The presence of the second set of gradient coils is effective in reducing the induced currents and in limiting the distortion of the gradients that is desired to produce, but the overall size is large, which from a practical point of view constitutes a drawback.

Those prior art systems achieve compensation by two sets of coils of the same type, either in conventional manner for the system described in WO 89/03031, or else in “tubes” for the system described above. Since the coils are of the same type, that necessarily results in the gradient created by the first coils on their own being attenuated, and the value desired for the gradient (e.g. gradients of about 70 milliteslas per meter (mT/m)) can be achieved only by sacrificing linearity.

### OBJECT AND DEFINITION OF THE INVENTION

The present invention seeks to remedy the above-mentioned drawbacks and to enable contradictory requirements to be satisfied by enabling a machine to be obtained that is compact, with magnetic field gradients of high nominal value, while nevertheless presenting excellent linearity, and with shielding that is effective so as to limit the currents that are induced in the outer conductive casings, with electrical resistance and inductance that are minimized, and with noise and vibration that are also small.

The invention also seeks to define a method of making such a device that is simplified while nevertheless making it possible to satisfy the above-mentioned contradictory requirements.

In outline, the invention consists in making a hybrid system combining a first set of conventional coils with a second set of coils in “tubes” with gradients that are mutually reinforcing instead of opposing in the volume of interest, while nevertheless achieving the outward compensation that is needed for attenuating eddy currents.

In accordance with the invention, these objects are achieved by a magnetic field gradient generator system arranged around a volume of interest (ZI) of axis Oz in a nuclear resonance imaging machine, the system being characterized in that it comprises at least solenoidal z-gradient first and second coils of axis Oz carrying currents in opposite directions; a set of identical z-gradient first tubes of axes parallel to the axis Oz, each comprising at least solenoidal third and fourth coils carrying currents in opposite directions and arranged in a ring outside the z-gradient first and second coils; at least x-gradient fifth to eighth coils of saddle shape and y-gradient ninth to twelfth coils of saddle shape arranged around the z-gradient first and second coils; a set of identical x and y-gradient second tubes of axes parallel to the axis Oz and situated in a ring outside the z-gradient first and second coils, being interposed between the z-gradient first tubes in the same ring, each of the x and y-gradient second tubes comprising at least solenoidal thirteenth and fourteenth coils carrying currents in opposite directions, the x and y directions being mutually orthogonal and orthogonal to the axis Oz.

More particularly, the invention provides a system for generating magnetic field gradients, which system is arranged in a first cylindrical annular space around a tunnel of axis Oz and of essentially circular section defining a volume of interest in a nuclear magnetic resonance imaging machine in order to create a magnetic field gradient in said volume of interest, the gradient generator system being characterized in that it comprises, inside the first cylindrical annular space, solenoidal z-gradient first and second coils each comprising the same plurality n1 of identical turns of axis Oz and of diameter less than the outside diameter of the first cylindrical annular space, the turns of the second coil carrying current in a direction opposite to the direction of current carried by the turns of the first coil in order to produce a first z-gradient field component in an axial direction z parallel to the axis Oz; a set of N1 identical non-touching first tubes of axes parallel to the axis Oz and arranged in a cylindrical annular sub-space situated inside said first cylindrical annular space outside said z-gradient first and second coils, each of the N1 first tubes comprising solenoidal z-gradient third and fourth coils that are symmetrical relative to a plane xOy perpendicular to the axis Oz, each comprising the same plurality N2 of identical turns of diameter less than the inside diameter of the corresponding tube and distributed in predetermined positions along the axis of the tube, the turns of the fourth coil arranged facing the second coil carrying current in a direction opposite to the direction of current carried by the turns of the second coil and to the direction of current carried by the turns of the third coil, itself arranged facing the first coil in order to produce a second z-gradient field component in said axial direction z parallel to the axis Oz; a set of x-gradient fifth, sixth, seventh, and eighth coils having a saddle-shaped configuration, each having a number n3 of turns, the x-gradient fifth, sixth, seventh, and eighth coils being arranged in the vicinity of the solenoidal z-gradient first and second coils in positions that are radially and longitudinally symmetrical relative to the axis Oz in order to produce a first x-gradient field component in a first radial direction x of the machine perpendicular to the axis Oz; a set of y-gradient ninth, tenth, eleventh, and twelfth coils having a saddle-shaped configuration, each having a number n4 of turns, the y-gradient ninth, tenth, eleventh, and twelfth coils being arranged in the vicinity of the solenoidal z-gradient first and second coils in positions that are radially and longitudinally symmetrical relative to the axis Oz, in superposition respectively with the x-gradient fifth, sixth, seventh, and eighth coils but offset at 90° relative to thereto in order to produce a first y-gradient field component in a second radial direction y of the machine likewise perpendicular to the axis Oz, the first direction x being perpendicular to the second direction y; a set of N2 identical non-touching second tubes parallel to the axis Oz and situated in said cylindrical annular sub-space situated inside said first cylindrical annular space outside said z-gradient first and second coils by being interposed between said first tubes, each of the N2 second tubes comprising solenoidal x and y-gradient thirteenth and fourteenth coils that are symmetrical relative to a plane xOy perpendicular to the axis Oz, each comprising the same plurality n5 of identical turns of diameter less than the inside diameter of the corresponding tube and distributed in predetermined positions along the axis of this tube, the turns of the fourteenth coil arranged facing the second coil carrying current in a direction opposite to the direction of current carried by the turns of the second coil and to the direction of current carried by the turns of the thirteenth coil, itself arranged facing the first coil in order to produce a second field component having both an x gradient and a y gradient.

In an advantageous particular embodiment, the solenoidal z-gradient first and second coils and the solenoidal z-gradient third and fourth coils are single-layer coils.

According to another preferred characteristic of the invention, the x-gradient fifth, sixth, seventh, and eighth coils and the y-gradient ninth, tenth, eleventh, and twelfth coils are single-layer coils, while the solenoidal x and y-gradient thirteenth and fourteenth coils are two-layer coils.

These characteristics are not limiting, and, by way of example, the solenoidal z-gradient coils may comprise two layers. The solenoidal x and y-gradient thirteenth and fourteenth coils may likewise comprise some number of layers other than two, e.g. three layers.

In a particular embodiment, the N2 second tubes are shorter than the N1 first tubes.

In a preferred embodiment, in the cylindrical sub-space, the gradient generator system comprises a ring of 12, 16, or 24 tubes made up of said second tubes alternating with said first tubes.

The invention also provides a nuclear magnetic resonance imaging machine with improved gradients, comprising a tunnel of axis Oz and of essentially circular section defining a volume of interest ZI, a first cylindrical annular space surrounding said volume of interest ZI and containing a magnetic field gradient generator system for creating a magnetic field gradient in said volume of interest ZI, an outer second cylindrical annular space forming a cryostat surrounding said first cylindrical annular space and including a superconductive magnet device for generating a uniform magnetic field component B_{Z} along said axis Oz in said volume of interest ZI, a radio frequency emission antenna device arranged inside said tunnel or in the vicinity thereof in the first cylindrical annular space, and electrical power supply devices for powering the gradient generator system and the antenna device, the machine being characterized in that the gradient generator system is a system made in the above-defined manner.

The invention also provides a method of providing a magnetic field gradient system arranged around a volume of interest (ZI) of axis Oz in a nuclear resonance imaging machine, the method being characterized in that it comprises the following steps:
forming at least solenoidal z-gradient first and second coils of axis Oz carrying currents in opposite directions;
forming a set of identical z-gradient first tubes parallel to the axis Oz, each comprising at least solenoidal third and fourth coils carrying currents in opposite directions and arranged in a ring outside the z-gradient first and second coils;
forming at least x-gradient fifth to eighth coils of saddle shape arranged around the z-gradient first and second coils;
forming at least y-gradient ninth to twelfth coils of saddle shape arranged around the z-gradient first and second coils;
forming a set of identical x and y-gradient second tubes of axes parallel to the axis Oz and situated in a ring outside the z-gradient first and second coils, being interposed between the z-gradient first tubes in the same ring, each of the x and y-gradient second tubes comprising at least solenoidal thirteenth and fourteenth coils carrying currents in opposite directions, the directions x and y being mutually orthogonal and orthogonal to the axis Oz; and
determining the characteristics of all of the solenoidal coils with the help of the regular solid spherical harmonic development of the component B_{Z} of the magnetic field created in the zone of interest (ZI) for each turn or turn arc of a solenoidal coil as a function of the power available for electrically powering the coils, of the outside diameter of the tunnel defining the zone of interest (ZI), and of the inside diameter of an outer second cylindrical annular space including a superconductive magnet device.

In more particular manner, the invention provides a magnetic field gradient generator system arranged in a first cylindrical annular space around a tunnel of axis Oz and of essentially circular section defining a volume of interest ZI in a nuclear magnetic resonance imaging machine having an outer second cylindrical annular space forming a cryostat surrounding said first cylindrical annular space and including a superconductive magnet device for generating a uniform magnetic field component B_{Z} along said axis Oz in said volume of interest ZI in order to create a magnetic field gradient in said volume of interest ZI, the method being characterized in that it comprises the following steps:
forming inside said first cylindrical annular space solenoidal z-gradient first and second coils each comprising the same plurality n1 of identical turns of axis Oz and of diameter less than the outside diameter of the first cylindrical annular space, the turns of the second coil carrying current in a direction opposite to the direction of current carried by the turns of the first coil in order to produce a first z-gradient field component in an axial direction z parallel to the axis Oz;
forming a set of N1 identical non-touching first tubes of axes parallel to the axis Oz and arranged in a cylindrical annular sub-space situated inside said first cylindrical annular space outside said z-gradient first and second coils, each of the N1 first tubes comprising solenoidal z-gradient third and fourth coils that are symmetrical relative to a plane xOy perpendicular to the axis Oz, each comprising the same plurality n2 of identical turns of diameter less than the inside diameter of the corresponding tube and distributed in predetermined positions along the axis of this tube, the turns of the fourth coil arranged facing the second coil carrying current in a direction opposite to the direction of current carried by the turns of the second coil and to the direction of current carried by the turns of the third coil, itself arranged facing the first coil in order to produce a second z-gradient field component in said axial direction z parallel to the axis Oz;
forming a set of x-gradient fifth, sixth, seventh, and eighth coils having a saddle-shaped configuration, each having a number n3 of turns, the x-gradient fifth, sixth, seventh, and eighth coils being arranged in the vicinity of the solenoidal z-gradient first and second coils in positions that are radially and longitudinally symmetrical relative to the axis Oz in order to produce a first x-gradient field component in a first radial direction x of the machine perpendicular to the axis Oz;
forming a set of y-gradient ninth, tenth, eleventh, and twelfth coils having a saddle-shaped configuration, each having a number n4 of turns, the y-gradient ninth, tenth, eleventh, and twelfth coils being arranged in the vicinity of the solenoidal z-gradient first and second coils at positions that are radially and longitudinally symmetrical relative to the axis Oz, in superposition respectively with the x-gradient fifth, sixth, seventh, and eighth coils but offset by 90° relative thereto in order to produce a first y-gradient field component in a first radial direction y of the machine that is likewise perpendicular to the axis Oz, the first direction x being perpendicular to the second direction y;
forming a set of N2 identical non-touching second tubes of axes parallel to the axis Oz and situated in said cylindrical annular sub-space situated inside said first cylindrical annular space outside said z-gradient first and second coils, being interposed between said first tubes, each of the N2 second tubes comprising solenoidal x and y-gradient thirteenth and fourteenth coils that are symmetrical relative to an xOy plane perpendicular to the axis Oz, each comprising the same plurality n5 of identical turns of diameter less than the inside diameter of the corresponding tubes and distributed in predetermined positions along the axis of this tube, the turns of the fourteenth coil arranged facing the second coil carrying current in a direction opposite to the direction of current carried by the turns of the second coil and to the direction of current carried by the turns of the thirteenth coil, itself arranged facing the first coil, in order to produce a second field component having both an x gradient and a y gradient; and
determining the characteristics of the set of solenoidal coils with the help of the regular solid spherical harmonic development of the component B_{Z} of the magnetic field created in the zone of interest by each turn or turn arc of a solenoidal coil as a function of the electrical power available for powering the coils, of the outside diameter of the tunnel defining the zone of interest, and of the inside diameter of said outer second cylindrical annular space including the superconductive magnet device.

### BRIEF DESCRIPTION OF THE DRAWINGS

Other characteristics and advantages of the invention appear from the following description of particular embodiments of the invention given as examples with reference to the accompanying drawings, in which:

FIG. 1 is a diagrammatic axial section view of a first example of a device for producing a magnetic field of hybrid z-gradient suitable for being included in a magnetic field generator system of the invention;

FIG. 1A shows a portion of FIG. 1 on a larger scale;

FIG. 2 is a diagrammatic axial section view of a second example of a device for producing a magnetic field of hybrid z-gradient suitable for including in a magnetic field generator device of the invention;

FIG. 2A shows a portion of FIG. 2 on a larger scale;

FIG. 3 shows a portion of FIG. 2A on a larger scale;

FIG. 4 is a diagrammatic view in section perpendicular to the axis showing the various subassemblies making up a system of the invention for generating hybrid gradients;

FIG. 5 shows a portion of FIG. 4 on a larger scale;

FIG. 5A shows a portion of FIG. 5 on an even larger scale;

FIG. 6 is a diagrammatic perspective view of the entire system of the invention for generating hybrid gradients;

FIG. 7 is a section view on plane VII-VII of FIG. 6;

FIG. 8 is a diagrammatic perspective view of a portion of the FIG. 6 system for generating hybrid gradients, showing a saddle-shaped first device for creating x and y gradients and an additional device for creating x and y gradients with the help of “tube” solenoidal coils;

FIG. 9 is a diagrammatic perspective view of a portion of the FIG. 6 system for generating hybrid gradients having a saddle-shaped first device for creating x and y gradients;

FIG. 10 is a diagrammatic perspective view of a portion of the FIG. 6 system for generating hybrid gradients comprising a first device for creating a z gradient with the help of conventional coils and an additional device for creating a z gradient with the help of “tube” solenoidal coils;

FIGS. 11 and 12 show two possible embodiments of saddle-shaped coils in a developed plan view, which coils are suitable for use in the context of the first device for creating x and y gradients;

FIGS. 13 to 18 show various embodiments of inter-turn transitions for saddle-shaped coils such as those of FIGS. 11 and 12 or for solenoidal coils; and

FIG. 19 is a diagrammatic view of an example of a prior art nuclear magnetic resonance imaging machine to which the invention is applicable.

### DETAILED DESCRIPTION OF PREFERRED EMBODIMENTS

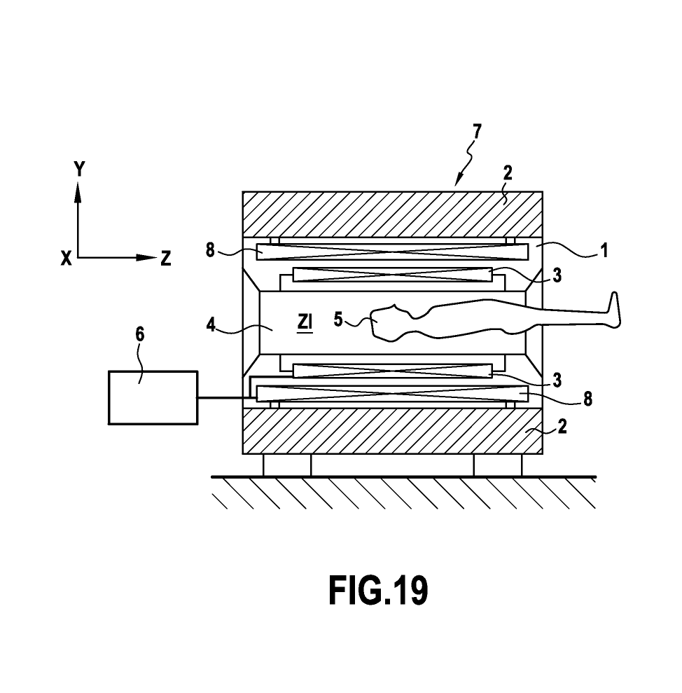

The principle of a magnetic resonance imaging (MRI) machine 7 to which the invention is applicable is initially summarized with reference to FIG. 19.

An outer cylindrical annular zone 2 incorporates a device for creating a main magnetic field B₀ that is uniform and intense and essentially parallel to the axis z of a tunnel 4 in which there is installed a patient 5 or an article for examination.

In preferred manner, the device for creating a uniform and intense main magnetic field B₀ comprises a superconductive magnet placed in a cryostat that serves to maintain the superconductive magnet at very low temperature. In any event, the device for creating an intense magnetic field is placed in the cylindrical annular outer enclosure 2 that leaves a cylindrical annular space 1 between the inner wall of the outer enclosure 2 and the tunnel 4.

A system 8 is arranged in the annular space for generating magnetic field gradients both in the direction of the axis z of the tunnel and in directions x and y that are mutually perpendicular and also perpendicular to the axis z.

As mentioned above, the coils 8 for generating gradients serve to create coding in the space in which the patient 5 is located by applying additional magnetic fields that are pulsed.

The components of these fields that are not oriented in the same way as the orienting field B₀ provide a contribution to modifying the working NMR signal that is of second order only (and thus negligible for the values under consideration of B₀ and of the gradients). Thus, the only component of these magnetic fields that are produced by the gradient coils and that is of interest and of use, is the component oriented along the field B₀. This useful component is conventionally referred to as the B_{Z} component. Positions within the machine are identified relative to a Cartesian frame of reference, the axis z being colinear with the direction of the uniform field B₀ and parallel to the generator lines of the tunnel machine. Depending on which sets of gradient coils are powered, the useful B_{Z} component at any one location has an amplitude that increases as a function of its position along the abscissa x of a plane containing that location and parallel to the yOz plane for x gradients, as a function of its position along the ordinate y of a plane containing that location and parallel to the xOz plane for the y gradients, or as a function of the z position of a plane containing that location and parallel to the xOy plane for the z gradients.

A device 3 having radiofrequency emitter antennas is arranged in the vicinity of the tunnel 4 or it is inserted directly in the tunnel. The radiofrequency emission antennas or coils are associated in conventional manner with devices for receiving and processing radiofrequency response signals that are emitted by the body of the patient 5 or by any other article under study, such as an animal, for example.

In FIG. 19, a power supply device 6 is represented symbolically for electrically powering both the gradient coils of the gradient generator system 8, and the radiofrequency emission antenna device 3.

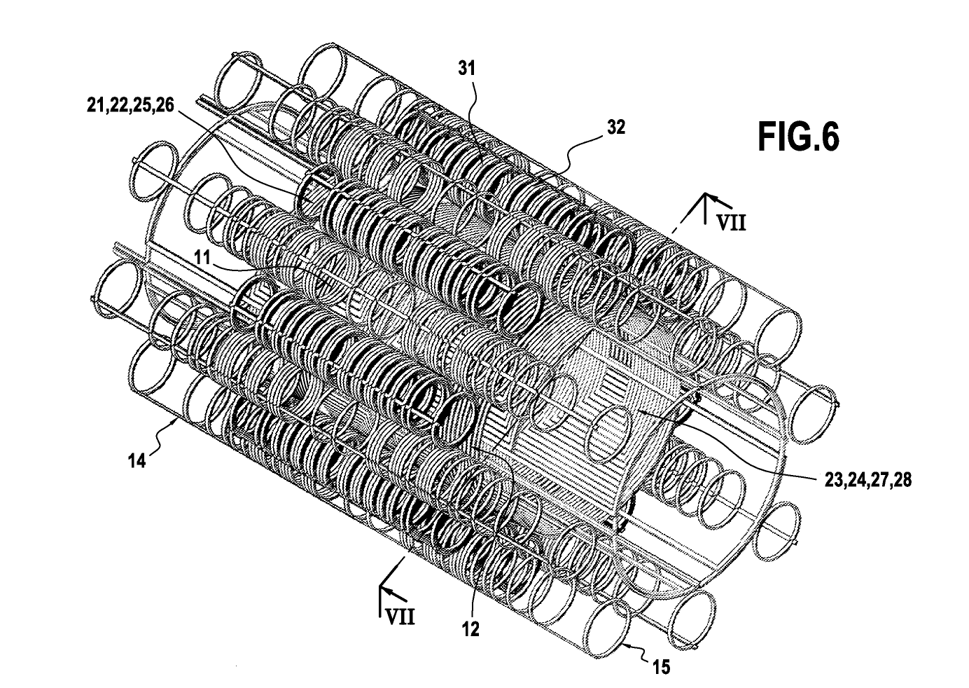

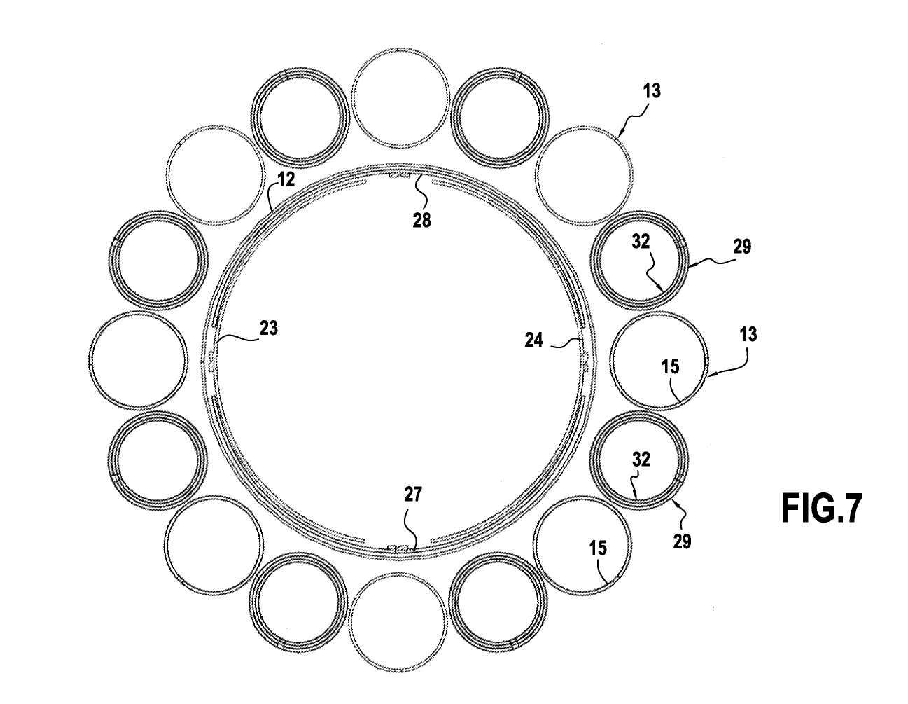

FIGS. 6 and 7 show all of the various elements making up the magnetic field gradient generator system 8 of the invention suitable for incorporating in a cylindrical annular space such as the space 1 in the MRI machine 7 shown diagrammatically in FIG. 19.

Inside the cylindrical annular space 1, the gradient generator system 8 firstly comprises first and second solenoidal z-gradient coils 11, 12 each having the same plurality n1 of identical turns of axis Oz and of diameter smaller than the outside diameter of the cylindrical annular space 1, the turns of the second coil 12 carrying current in a direction opposite to the direction of current carried by the turns of the first coil 11 in order to produce a first z field gradient component in an axial direction z parallel to the axis Oz.

The gradient generator system 8 secondly comprises a set N1 of first identical non-touching tubes 13 of axes parallel to the axis Oz and arranged in a cylindrical annular sub-space 9 situated inside the cylindrical annular space 1 outside the first and second z-gradient coils 11, 12, each of the first tubes 13 comprising third and fourth solenoidal z-gradient coils 14, 15 that are symmetrical about an xOy plane perpendicular to the axis Oz, each having the same plurality n2 of identical turns of diameter less than the inside diameter of the corresponding tube 13 and distributed in predetermined positions along the axis of the tube 13, the turns of the fourth coil 15 arranged facing the second coil 12 carrying current in a direction opposite to the direction of current carried by the turns of the second coil 12 and to the direction of current carried by the turns of the third coil 14, itself arranged facing the first coil 11 so as to produce a second z field gradient component in the direction z parallel to the axis Oz.

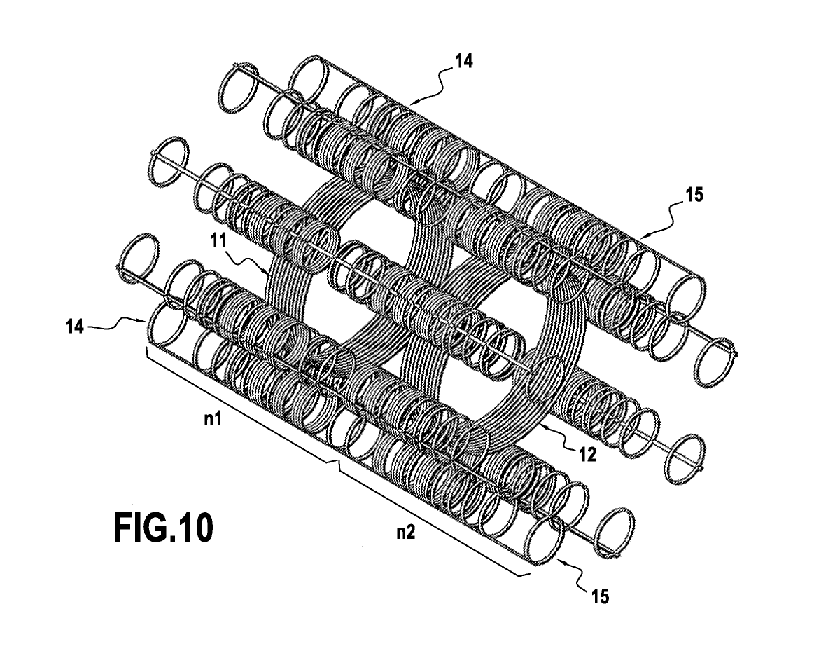

FIG. 10 is a perspective view of an example of coils 11 and 12 co-operating with a plurality of pairs of coils 14, 15 arranged in a ring around the coils 11 and 12 and shown without the tubes 13.

FIG. 4 shows an example of how tubes 13 may be arranged around the coils 11 and 12.

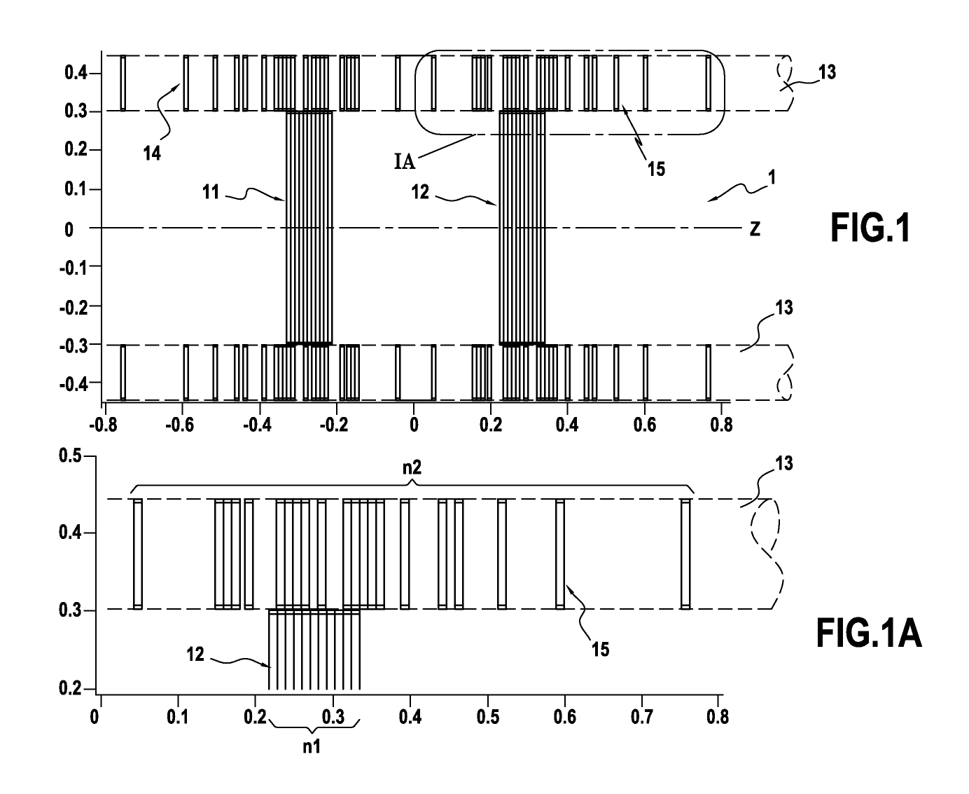

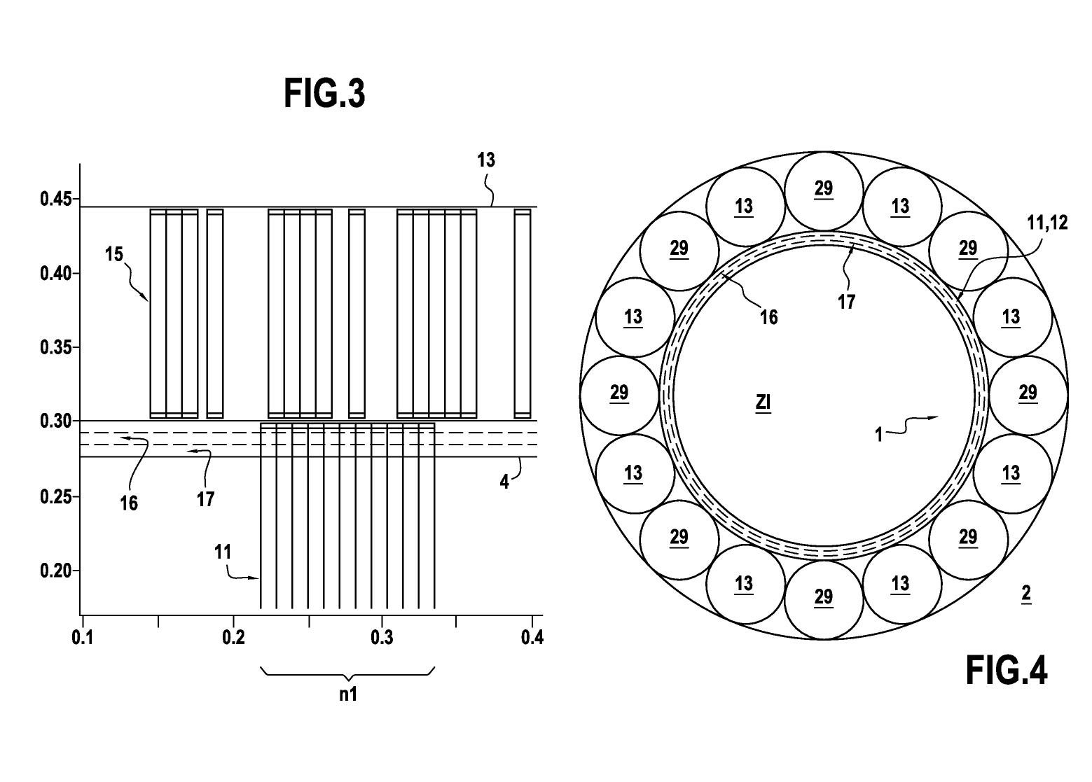

FIGS. 1, 1A, and 3 show a first example of how z-gradient coils 11, 12 of axis Oz may be associated with pairs of coils 14, 15 placed in tubes 13 of axis parallel to the axis Oz and arranged in a ring around the coils 11, 12. This first embodiment serves to cancel the component Z₃ in a regular spherical harmonic development (RHD). By way of example, the coils 11, 12 may have a number n1 equal to 11 grouped-together turns that are juxtaposed along the axis Oz.

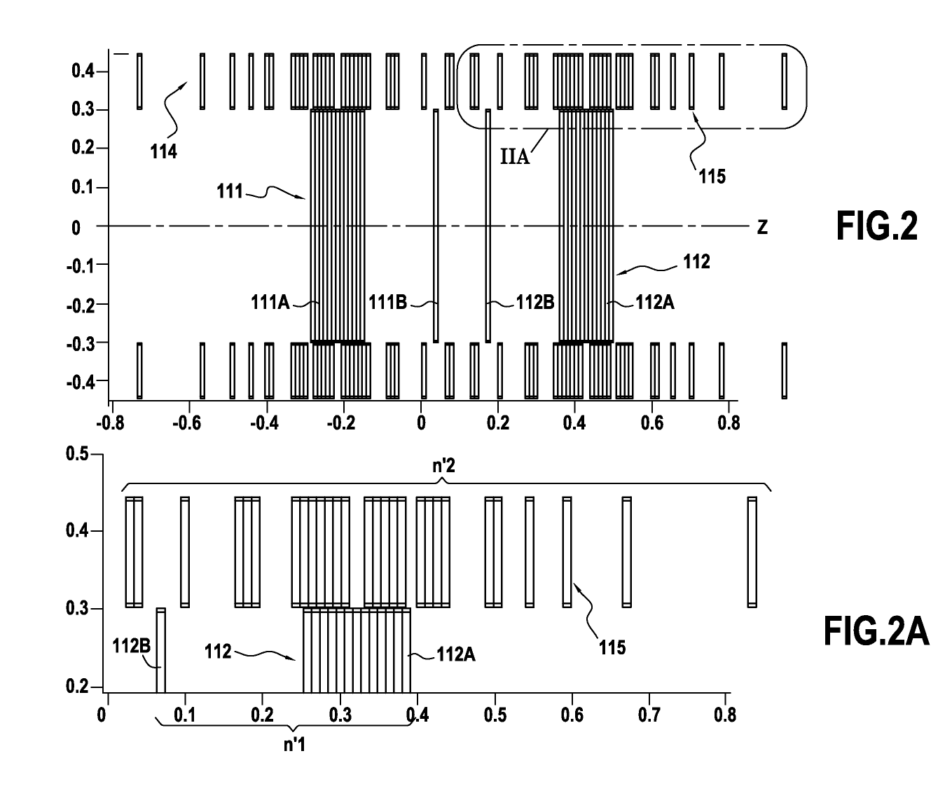

FIGS. 2 and 2A show a second example of how z-gradient coils 111, 112 of axis Oz may be associated with pairs of coils 114, 115 placed in tubes 13 of axis parallel to the axis Oz and arranged in a ring around the coils 111, 112. This second embodiment serves to cancel the Z₃ and Z₅ components in a regular spherical harmonic development (RHD). Under such circumstances, each of the coils 111 and 112 has a number n′1 of turns, e.g. with a first group 111A, 112A of 13 grouped-together turns juxtaposed along the axis Oz and an isolated additional turn 111B, 112B that is offset along the axis Oz. The number n′2 and the spacing between the turns of the coils 114 and 115 along the axis Oz are likewise different from the number n2 and the distribution of the turns of the coils 14 and 15 along the axis Oz. The RHD is calculated over all of the coils 11, 12, 14, and 15 in order to cancel the Z₃ component or over all of the coils 111, 112, 114, and 115 to cancel the components Z₃ and Z₅.

The assembly constituted by coil pairs 11, 12 and 14, 15, or the assembly constituted by coil pairs 111, 112 and 114, 115 constitutes a system of hybrid gradients along z.

The gradient generator system 8 also has systems of hybrid gradients along x and along y.

Thus, the gradient generator system 8 further comprises a set of x-gradient fifth, sixth, seventh, and eighth coils having a saddle-shaped configuration, each having a number n3 of turns, the x-gradient fifth, sixth, seventh, and eighth coils 21, 22, 23, 24 being arranged in the vicinity of the solenoidal z-gradient first and second coils 11 and 12 in positions that are radially and longitudinally symmetrical relative to the axis Oz in order to produce a first x-gradient field component in a first radial direction x of the machine perpendicular to the axis Oz.

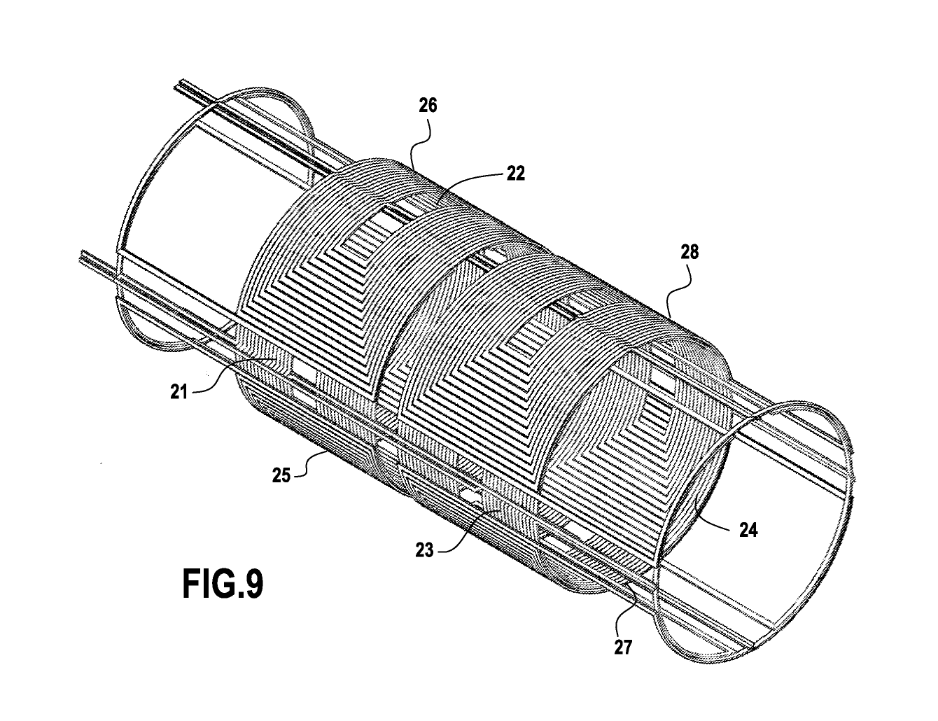

In order to produce hybrid gradient systems along x and along y, the gradient generator system 8 fourthly comprises a set of y-gradient ninth, tenth, eleventh, and twelfth coils 25, 26, 27, 28 having a saddle-shaped configuration, each having a number n4 of turns, the y-gradient ninth, tenth, eleventh, and twelfth coils 25, 26, 27, 28 being arranged in the vicinity of the solenoidal z-gradient first and second coils 11, 12 in positions that are radially and longitudinally symmetrical relative to the axis Oz, being superposed respectively with the x-gradient fifth, sixth, seventh, and eighth coils 21, 22, 23, 24, but offset at 90° relative thereto in order to produce a first y-gradient field component in a second radial direction y of the machine that is likewise perpendicular to the axis Oz, the first direction x being perpendicular to the second direction y. FIG. 9 shows a possible implementation of the coils 21 to 24 and 25 to 28 for creating a first x and y-gradient component.

Finally, in order to make hybrid gradient systems along x and along y, the gradient generator system 8 fifthly comprises a set of N2 identical non-touching second tubes 29 of axes parallel to the axis Oz and situated in the cylindrical annular sub-space 9 situated inside the first cylindrical annular space 1 outside the z-gradient first and second coils 11, 12, being interposed between the first tubes 13, each of the N2 second tubes 29 having solenoidal x-gradient and y-gradient thirteenth and fourteenth coils 31 and 32 that are symmetrical about a plane xOy perpendicular to the axis Oz, each having the same plurality n5 of identical turns of diameter smaller than the inside diameter of the corresponding tube 29 and distributed in predetermined positions along the axis of the tube 29, the turns of the fourteenth coil 32 arranged facing the second coil 12 carrying current in a direction opposite to the direction of current carried by the turns of the second coil 12 and to the direction of current carried by the turns of the thirteenth coil 31, itself arranged facing the first coil 11 in order to produce a second field component that is simultaneously of x gradient and of y gradient.

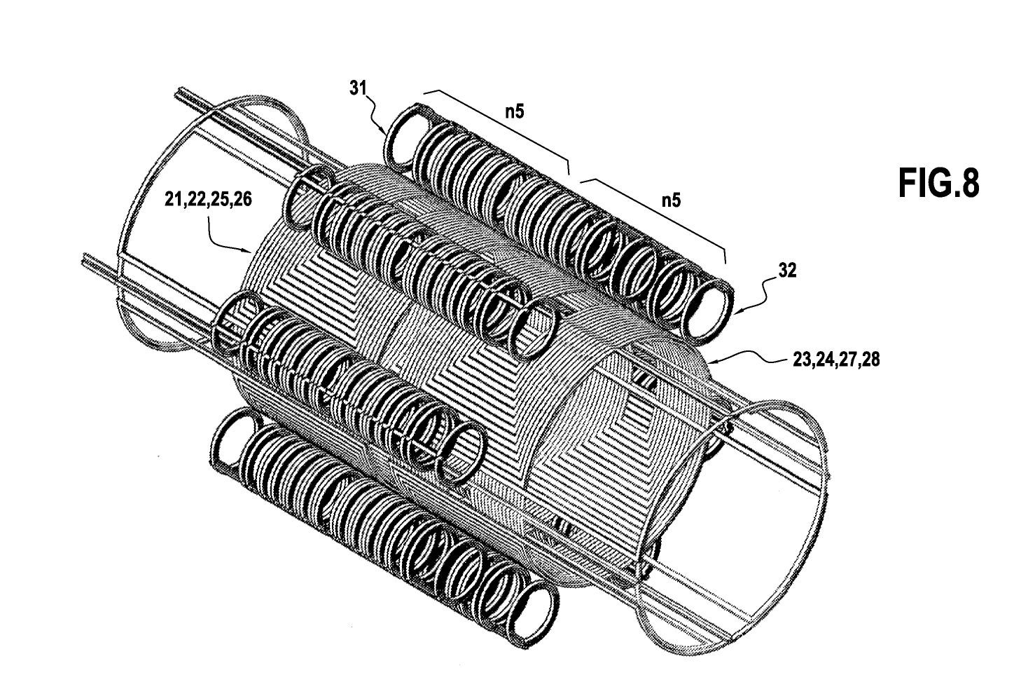

FIG. 8 shows a possible implementation both of the coils 21 to 24 and 25 to 28 together with a plurality of pairs of coils 31, 32 distributed in a ring along the coils 21 to 24 and 25 to 28 in order to create hybrid x and y gradients.

There follows a description of certain calculations that make it possible to determine the characteristics of the various coils making up the hybrid gradient generator system 8.

For calculation purposes, consideration is given to basic elements constituted by arcs of circular turns (or by complete turns) about the axis Oz and circular turns about axes O′z′ parallel to Oz.

From the fundamental electromagnetism equations, it is possible to establish analytic expressions for the components of the magnetic vector potential and field generated by such elements at all points in three-dimensional space, together with the coefficients Zₙ, Xₙ^{m} and Yₙ^{m} of the development in regular solid spherical harmonics (RHD) of the B_{Z} component of the magnetic field they create in the region of interest (ROI) that is referenced ZI in the vicinity of the point by using the following expressions:

$${B}_{z} = {Z}_{0} + {\sum }_{n = 1}^{∞} {r}^{n} [ {Z}_{n} {P}_{n} ( cos ϑ ) + {\sum }_{m = 1}^{n} ( {X}_{n}^{m} cos m ϕ + {Y}_{n}^{m} sin m ϕ ) {P}_{n}^{m} ( cos ϑ ) ]$$

A few examples of these expressions are given below.

### 1.1 Components of the Vector Potential and of the Field of a Turn at any Point

Consider a circular turn of axis Oz, of radius a, centered at a point at position b, and carrying a current I measured algebraically around Oz. At a point having cylindrical coordinates (ρ, φ, z), the only non-zero components of the vector potential and of the field are given by the following expressions:

$${A}_{ϕ} = \frac{{μ}_{0} I}{2 π} \frac{{r}_{1}}{ρ} [ ( 1 - \frac{{k}^{2}}{2} ) K ( k ) - E ( k ) ]$$

$${B}_{ρ} = \frac{{μ}_{0} I}{2 π} \frac{b - z}{ρ {r}_{1}} [ K ( k ) - \frac{{a}^{2} + {ρ}^{2} + {( b - z )}^{2}}{{r}_{2}^{2}} E ( k ) ]$$

$${B}_{z} = \frac{{μ}_{0} I}{2 π} \frac{1}{{r}_{1}} [ K ( k ) + \frac{{a}^{2} - {ρ}^{2} - {( b - z )}^{2}}{{r}_{2}^{2}} E ( k ) ]$$

where K(k) and E(k) are the complete elliptical integrals of the first and second kinds respectively, using the following notation:

$$k = \frac{2 \sqrt{a ρ}}{{r}_{1}}$$

$${r}_{1} = \sqrt{{( a + ρ )}^{2} + {b}^{2}}$$

$${r}_{2} = \sqrt{{( a - {ρ}_{0} )}^{2} + {b}^{2}}$$

For an arc of a turn, there is no longer symmetry of revolution and all of the components exist with expressions that are more or less complicated and that involve incomplete elliptical integrals.

### 1.2 RHD of an Arc of a Turn

Consider an arc of a turn of axis Oz, of radius a, and of position b, carrying a current I between angles ψ₁ and ψ₂, measured algebraically around Oz.

Using the notation

$$c = \sqrt{{a}^{2} + {b}^{2}}$$

$$and$$

$$cos α = \frac{b}{c} ,$$

0≦a≦π, the following result is obtained:

$${B}_{z} = \frac{{μ}_{0} I}{2 c} \frac{( {ψ}_{2} - {ψ}_{1} )}{2 π} {\sum }_{n = 0}^{∞} {( \frac{r}{c} )}^{2} sin α {P}_{n + 1}^{1} ( cos α ) {P}_{n} ( cos ϑ ) + \frac{{μ}_{0} I}{c} \frac{1}{π} {\sum }_{n = 1}^{∞} {( \frac{r}{c} )}^{n} {\sum }_{m = 1}^{n} \{ \begin{matrix}\frac{( n - m ) !}{( n + m ) !} [ \frac{1}{m} sin α {P}_{n + 1}^{m + 1} ( cos α ) - {P}_{n}^{m} ( cos α ) ] \times \\ sin m \frac{{ψ}_{2} - {ψ}_{1}}{2 π} cos m ( ϕ - \frac{{ψ}_{1} - {ψ}_{2}}{2} )\end{matrix} \} {P}_{n}^{m} ( cos ϑ )$$

For a complete turn ψ₂=ψ₁=2π, thus reducing to the well-known elementary result:

$${B}_{z} = \frac{{μ}_{0} I}{2 c} {\sum }_{n = 0}^{∞} {( \frac{r}{c} )}^{2} sin α {P}_{n + 1}^{1} ( cos α ) {P}_{n} ( cos ϑ )$$

1.3 RHD for a Turn of Axis that is Offset

Consider a circular turn of axis O′z′, of radius a, and of position b, carrying a current I. The cylindrical coordinates in the Oxyz frame of reference relative of the center Ω of the turn are written (ρ₀, φ₀, b) and the trace O′ of O′z′ on the xoy plane has the cylindrical coordinates (ρ₀, φ₀, 0). The analytical expressions for the coefficients of the RHD involve complete elliptical integrals of the first kind, K(k), and of the second kind, E(k). They become increasingly large with increasing degree n and order m, but they can be manipulated very easily with a symbolic computation software package, e.g. such as that known under the name Maple. The corresponding expressions for n=m=1 are given below:

$${Z}_{1} = \frac{{μ}_{0} I}{2 π} \frac{b}{{r}_{1}^{3} {r}_{2}^{2}} [ ( {ρ}_{0}^{2} - {a}^{2} + {b}^{2} ) K ( k ) - \frac{\begin{matrix}{( {ρ}_{0}^{2} - {a}^{2} + {b}^{2} )}^{2} + \\ 4 {a}^{2} ( 2 {ρ}_{0}^{2} - 2 {a}^{2} - {b}^{2} )\end{matrix}}{{r}_{2}^{2}} E ( k ) ]$$

$$\begin{matrix}{X}_{1}^{1} \\ {Y}_{1}^{1}\end{matrix} = \frac{{μ}_{0} I}{2 π} \frac{1}{{ρ}_{0} {r}_{1}^{3} {r}_{2}^{2}} \{ \begin{matrix}[ {( {ρ}_{0}^{2} - {a}^{2} )}^{2} + {b}^{2} ( {ρ}_{0}^{2} + {a}^{2} ) ] K ( k ) - \\ \frac{\begin{matrix}{( {ρ}_{0}^{2} - {a}^{2} )}^{2} ( {ρ}_{0}^{2} + {a}^{2} + 2 {b}^{2} ) + \\ {b}^{4} ( {ρ}_{0}^{2} + {a}^{2} ) - 8 {ρ}_{0}^{2} {a}^{2} {b}^{2}\end{matrix}}{{r}_{2}^{2}} E ( k )\end{matrix} \} \begin{matrix}cos {ϕ}_{0} \\ sin {ϕ}_{0}\end{matrix}$$

$$k = \frac{2 \sqrt{a {ρ}_{0}}}{{r}_{1}}$$

$${r}_{1} = \sqrt{{( a + {ρ}_{0} )}^{2} + {b}^{2}}$$

$${r}_{2} = \sqrt{{( a - {ρ}_{0} )}^{2} + {b}^{2}}$$

The gradient system 8 needs to be inserted in the empty circular opening (of diameter that is typically 900 millimeters (mm)) in the main magnet situated in the outer cylindrical annular space 2, while leaving an empty circular opening for the tunnel 4 (which opening may typically have a diameter of at least 550 mm) that is sufficient to enable the patient to be inserted and the antennas 3 to be installed.

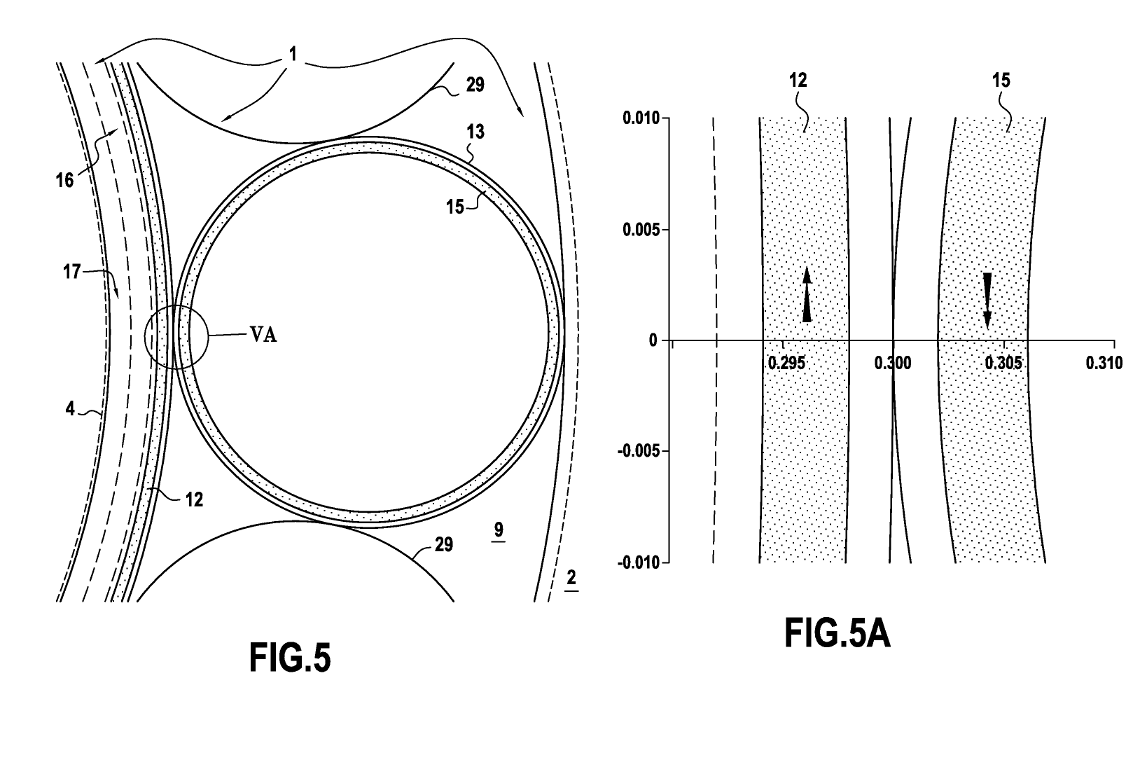

There needs to be a certain amount of radial thickness for the conventional gradient layers comprising two layers 16, 17 of saddle-shaped coils 21 to 24 and 25 to 28 for the x and y gradients and one layer of z-gradient coils 11, 12 (or 111, 112), inside the ring of tubes 13 and 29 (see FIGS. 4, 5 and 7). In this preferred solution with three conventional layers 12 and 13, 16 and 17 (for the z gradient and for the x, y gradients) situated inside the annular space occupied by the tubes 13, 29, each layer 12 and 13, 16 and 17 occupies a radial space of about 8 mm.

These considerations make it possible to determine the number and the diameter of the tubes 13, 29 that are to occupy as much as possible of the available space. In a preferred example, this leads to a preferred number of 16 tubes 13 or 29, with eight tubes referenced 13 (every other one of them) being devoted to the z gradient and the eight other tubes referenced 29 being devoted to the x and y gradients by superposing corresponding currents in the same coils 31, 32.

It should be observed that depending on the amount of space available, it is possible to envisage other combinations and thus other numbers for the N1 tubes 13 and the N2 tubes 29, the total number N1+N2 of tubes 13, 29 increasing if the total radial thickness of the gradient generator 8 is smaller. For example, it is thus possible to envisage a total number N1+N2 of tubes that is equal to 12 or 24 instead of 16.

Unlike that which is possible for gradient devices having single tubes, i.e. for a gradient generator that includes neither the coils 11, 12 (or 111, 112) producing a first z-gradient component, nor the saddle-shaped coils 21 to 24 and 25 to 28 producing a first x and y-gradient component, it is not possible to obtain simultaneously both linearity and shielding (i.e. a reduction in induced currents) while causing the coils 14, 15 or 114, 115 for the z gradient to cohabitate with the coils 31, 32 for the x and y gradients in the same tubes, which is why the tubes are separated into two families of tubes 13 and 29 respectively. As can be seen in FIG. 6, the coils 31 and 32 may be shorter than the coils 14 and 15 or 114 and 115, and consequently the tubes 13 incorporating the coils 31 and 32 may be shorter than the tubes 29 incorporating the coils 14 and 15 or 114 and 115.

A gradient generator system 8 presents constraints in terms of cooling and electrical power.

Thus, the amplifiers and the electronic components available for them that are incorporated in the power supply device 6 shown in FIG. 19 determine the nominal current in the conductors (which are typically made of copper) of the system 8 and also the maximum acceptable voltage while generating the current pulses that correspond to the selected imaging sequence.

This nominal current is typically several hundreds of amps (e.g. 625 A in the examples described) and it determines the minimum section for conductors that is compatible with means for removing heat by circulating a cooling fluid (water, oil, air, . . . ). The sections of the conductors may be different for the coils in the tubes and for the conventional coils, but it is typically several tens of square millimeters (mm²), e.g. a flat copper section of 10×4 mm², in the examples described.

In the tubes 13 or 29, the coils are constituted by circular turns at positions determined on one or more layers (z-gradient coils 14, 15 or 114, 115), e.g. two layers (x and y-gradient coils 31, 32). By way of example, dimensioning may be performed in compliance with the teaching of document WO 2005/029110 A2.

For the “conventional” layers, the z-gradient coils 11, 12 or 111, 112 are circular turns of axis Oz at determined positions in a single layer, while the x-gradient or y-gradient coils 21 to 24 and 25 to 28 are rectangular saddles of positions and dimensions that are determined in accordance with patent document EP 0 221 810 A1 or WO 89/03031 A, for example, or else saddles of more complex shape, e.g. in accordance with patent documents U.S. Pat. No. 4,617,516 A or EP 0 140 259 B1.

According to an important aspect of the present invention, the characteristics of the set of solenoidal coils are determined with the help of the regular solid spherical harmonic development of the B_{Z} component of the magnetic field that is created in the zone of interest ZI by each turn or turn arc of a solenoidal coil, as a function of the power available for electrically powering the coils, of the outside diameter of the tunnel 4 defining the zone of interest ZI, and of the inside diameter of the second outer cylindrical annular space 2 including the superconductive magnet device. Each hybrid gradient device, e.g. made up of the elements 11 to 15 for the z gradient and of the elements 21 to 24, 25 to 28, 29, 31, 32 for the x and y gradients, comprising both a “conventional” device and a “tube” device is determined overall from the RHD as mentioned above.

Various considerations are given below concerning obtaining an optimum configuration for the z gradient.

In each of the N2 tubes 13 dedicated to the z gradient, there are arranged 2×n₂ turns of the greatest possible diameter (coils 14 and 15), of axial positions that constitute unknowns that are to be determined. The turns are geometrically symmetrical relative to the midplane xOy and they carry currents in opposite directions.

There are also 2×n₁ turns of the diameter corresponding to the z conventional layer (coils 11, 12) having axial positions that are likewise unknowns to be determined. These turns satisfy the same properties of geometrical symmetry and of antisymmetric currents as the coils 14, 15 incorporated in the tubes 13.

Finally, the currents in the turns of the coils 14, of the tubes 13 and in the conventional turns 11, 12 on a given side of the xOy plane are in opposite directions, thereby producing z-gradient fields that add in the ROI whereas their vector potential azimuth components on the outside compensate one another.

Since all of these turns convey the same nominal currents in absolute value and in the above-specified directions, it is necessary to determine the integer numbers n₁ and n₂ and also the n₁+n₂ axial positions of the turns for producing a z gradient having a given magnitude (e.g. 70 mT/m in the examples given below), while possessing the desired linearity quality and the desired level of shielding.

Given the symmetries imposed for the shape and for the currents, the only non-zero terms of the RHD in the ROI are axial terms of odd degree, i.e. Z₁ which gives the magnitude of the gradient and Z₃, Z₅, Z₇, . . . that characterize the linearity.

It should be observed that in addition to the axial terms, the N2 tubes generate coefficients Xₙ^{m} and Yₙ^{m}, and n≧N₂, which coefficients are therefore negligible providing N2 is not too small, as explained in the patents concerning the gradients in tubes (see for example document WO 2005/029110 A2 or document WO 2007/048983 A2).

The formulas given above provide analytical expressions for these values Z₂ₚ₊₁ as a function of the unknown n₁+n₂ positions, including the value Z₁, i.e. the gradient. A first step for obtaining good linearity is to impose the condition Z₃=0, which suffices in practice (see FIGS. 1 and 1A), and if it is desired to do even better, then it is possible to impose the condition Z₃=Z₅=0 (see FIGS. 2 and 2A).

Furthermore, Maxwell's equations indicate that the origin of the current induced in the outer conductive coverings of the gradient system 8 is the variation over time in the azimuth component of the vector potential. In order to achieve shielding and using the formulas mentioned above together with their analytical expressions, it is ensured that the modulus of this component does not exceed a maximum value that is set at a certain number of points in the region occupied by the conductive coverings. Since the functions are continuous and since the vector potential decreases with distance from its sources, this condition is imposed on the modulus for a set of points situated on the generator line of a circular cylinder (e.g. 50 points that are regularly distributed between the position 0 and the position at 2 meters (m) on a cylinder having a radius of 0.5 m, assuming that the outside diameter of the gradient system is 0.45 m).

This thus amounts to a non-linear optimization problem in which the target function to be maximized is Z₁ with non-linear conditions (equalities for linearity, inequalities for shielding). Given that analytical expressions are available for the target function and for the constraints, it is possible to use the general subprograms of mathematical libraries, such as for example the E04UCF or E04WDF subprograms of the NAG library, which library is freely accessible on-line using the following links:

http://www.nag.co.uk/numeric/fl/nagdoc_f122/pdf/E04/e04ucf.pdf
http://www.nag.co.uk/numeric/fl/nagdoc_f122/pdf/E04/e04wdf.pdf

The values of n₁ and of n₂ must be given a priori and the final values are the result of a succession of tests performed iteratively.

Once the positions have been obtained, the electrical resistance and the inductance of the assembly can be calculated using conventional electromagnetism methods.

Various considerations are given below concerning obtaining the optimum configuration for the x or y gradients.

In principle, the procedure is identical to that described above for the z gradient. The conventional portion requires one layer 16 for the x gradient and a separate layer 17 for the y gradient, each of the layers 16, 17 being constituted by four saddle coils 21 to 24 or 25 to 28 respectively, e.g. in application of the teaching of the above-mentioned patent documents (EP 0 221 810 A1 or WO 89/03031 A, U.S. Pat. No. 4,617,516 A or EP 0 140 259 B1).

The portion in tubes 29 uses the same coils 31 and 32 for generating both the x gradient and the y gradient by superposing the currents needed for each of them. The current portion that generates the x gradient is proportional to cos φ₀, where φ₀ is the azimuth angle of the tube being powered, whereas the portion of the current that generates the y gradient is proportional to sin φ₀.

The total x gradient is equal to the coefficient X₁¹ of the RHD, while the total y gradient is equal to Y₁¹. The linearity of the component B_{Z} of the field created by each of the gradients is obtained by imposing the conditions X₃¹=X₃³=0 for the x gradient and also X₅¹ if better linearity is desired, and by imposing similar conditions with X→Y for the y gradient.

Whereas for the z gradient the source exciting the induced current is the azimuth component of the vector potential, it can be shown that for the x or y gradients the main exciting sources are the cos φ or sin φ Fourier components respectively of the radial component B_{ρ} of the magnetic field generated in the conductive coverings. The framing constraints leading to the desired shielding are thus applied to these Fourier components, for which it is possible to provide analytical expressions using the above-mentioned formulas, with the procedures being the same as those imposed on the azimuth component of the vector potential for the z gradient.

It should be observed that the directions of the currents in the saddles 21 to 24, 25 to 28 and in the tubes 29 are imposed a priori so that their contributions to the gradients add while their contributions to exciting induced currents in the outer coverings subtract, this constituting one of the essential characteristics of the invention.

The problem of non-linear optimization is similar to that described above for the z gradient, the target function to be maximized now being X₁¹ or Y₁¹ with the above-explained non-linear conditions (equalities of linearity, inequalities for shielding).

Tests leading of the number n₃ or n₄ of turns in each saddle 21, 22, 23, 24, 25, 26, 27, or 28, and to the number n₅ of turns in the coils 31, 32 of each of the tubes 29 show that the coils of the x and y-gradient coils 29 need to be closer to the midplane than the coils of the z-gradient tubes 13, and that it is therefore necessary to arrange them in a plurality of layers, e.g. two or three layers.

It should also be emphasized that it is preferable to use the technique of patents EP 0 221 810 A1 or WO 89/03031 A for the saddles made up exclusively firstly of circular turn arcs for which analytical expressions are known concerning the field components and the RHD, and secondly of portions parallel to Oz that do not contribute to the B_{Z} component of the field in the ROI and for which analytical expressions are also known for their contributions to the radial components B_{ρ} on the outside, in comparison with other techniques for which such analytical expressions are not known, thus constituting a serious handicap for the optimization process.

As for the z gradient, this process makes it possible to determine n₃, n₄, and the corresponding positions of the turns of the saddles and of the tubes, with examples being shown in the figures. It then remains to use conventional methods to calculate the electrical resistance and inductance in each of the x and y assemblies.

The present invention seeks to provide a gradient generator 8 that provides improved performance in spite of severe conditions of use.

The invention is adapted to nominal gradient values of about 70 mT/m that are obtained by using amplifiers that, by way of example, may be made using insulated gate bipolar transistor (IGBT) technology and that may operate using a voltage of 2 kilovolts (kV), a current of 625 A, and a mean power of 70 kilowatts (kW).

The coils should be made in such a manner as to present minimum electrical resistance and also minimum inductance, while also being installed in a small circularly-cylindrical annular space and presenting good geometrical quality in order to produce a magnetic field component B_{Z} that is as linear as possible. The compensation coils used for shielding in order to limit the current induced in the outer conductive coverings must be capable of limiting noise and vibration without attenuating the magnetic field gradients created by the basic coils.

In the hybrid gradient generator system 8 of the invention, use is made of basic coils that are constituted by “conventional” gradient devices for generating useful magnetic field gradients, and of compensation (shielding) coils that are constituted by coils in “tubes”, thereby solving a non-linear optimization problem with non-linear constraints and limits by means of an analytical method and a regular solid spherical harmonic development of the components of the magnetic field created in the field of interest by the coil elements (turn or turn arc) in order to determine the means for creating linear gradients, and an analytical method is also used to determine the characteristics of the shielding elements and to define the non-zero components of the vector potential and of the field at a point having cylindrical coordinates (ρ, φ, z) by using Fourier series in φ, Fourier-Bessel series in ρ, and a Fourier transform in z.

The hybrid gradient generator system 8 has at least two surface sheets of current per gradient direction on circular cylinders of axis Oz in order to generate the basic gradient.

Each surface sheet comprises the cylindrical coils 11, 12 or 111, 112 for the z gradient or saddle-shaped coils 21 to 24 and 25 to 28 for the x and y gradients, and may be made up of filament conductors of circular or rectangular section or of cutout cylindrical tubes, where appropriate.

For generating compensation gradients (shielding), the hybrid gradient generator system 8 has solenoidal coils of axes that constitute equidistant generator lines of a cylinder about the axis Oz. There are thus coils 14, 15 or 114, 115 for the z gradient and coils 31 and 32 for the x and y gradients.

The nominal current is imposed by the amplifier and determines the section selected for the conductive channels, taking account of the technique used for cooling. For example, for a nominal current of 625 A, it is possible to select a conductor section with an area of about 40 mm².

As mentioned above, the use of gradient generator devices in “tubes” both for generating source gradients and for shielding, e.g. as proposed in document WO 2007/048983 A2 is effective to a certain degree but occupies too much space in the radial direction, thereby limiting practical applications.

Furthermore, the use of shielding with the help of “conventional” gradient devices (saddle coils or solenoidal coils centered on the axis Oz) leads to induced currents that attenuate the source gradients created by “conventional” gradient devices or even by “tube” type devices arranged in a ring. The outer secondary layer needed for shielding decreases the gradient generated by the inner primary layer and the value desired for the gradient can be obtained only by sacrificing linearity.

In contrast, with a hybrid gradient generator system 8 of the invention, conventional gradient devices are used for producing source gradients and they occupy little space in the radial direction, while gradient devices in “tubes” are used for the outer shielding that produce induced currents that by their very nature, stemming from the design of gradient devices in “tubes”, serve to reinforce the source gradients. This provides a gradient generator system 8 that is both compact and effective and that enables excellent linearity to be conserved.

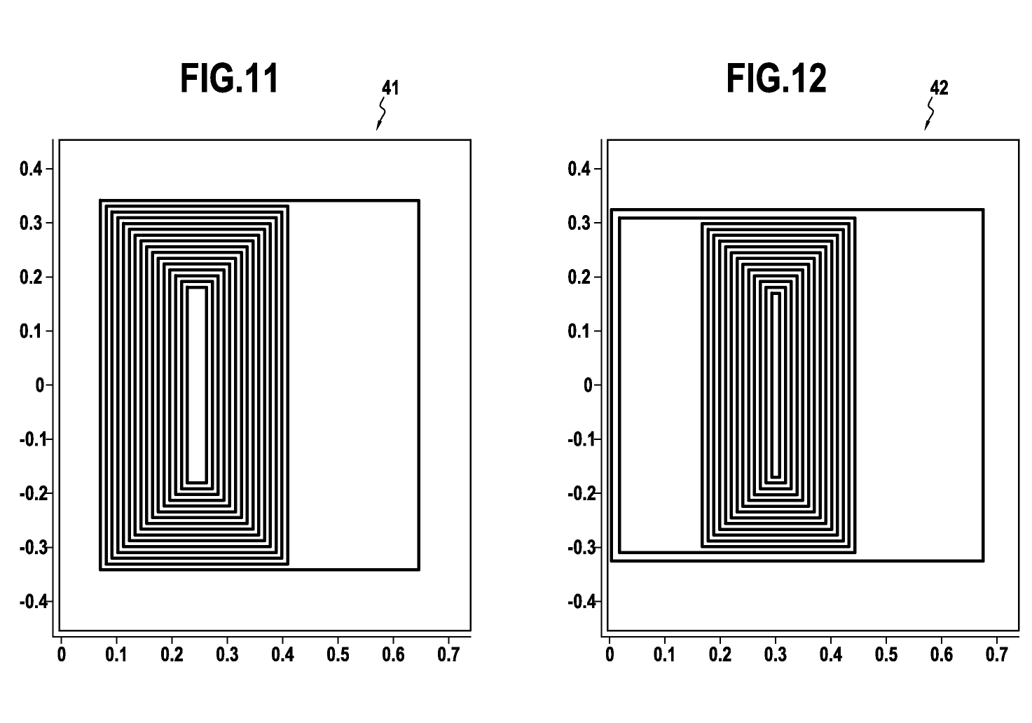

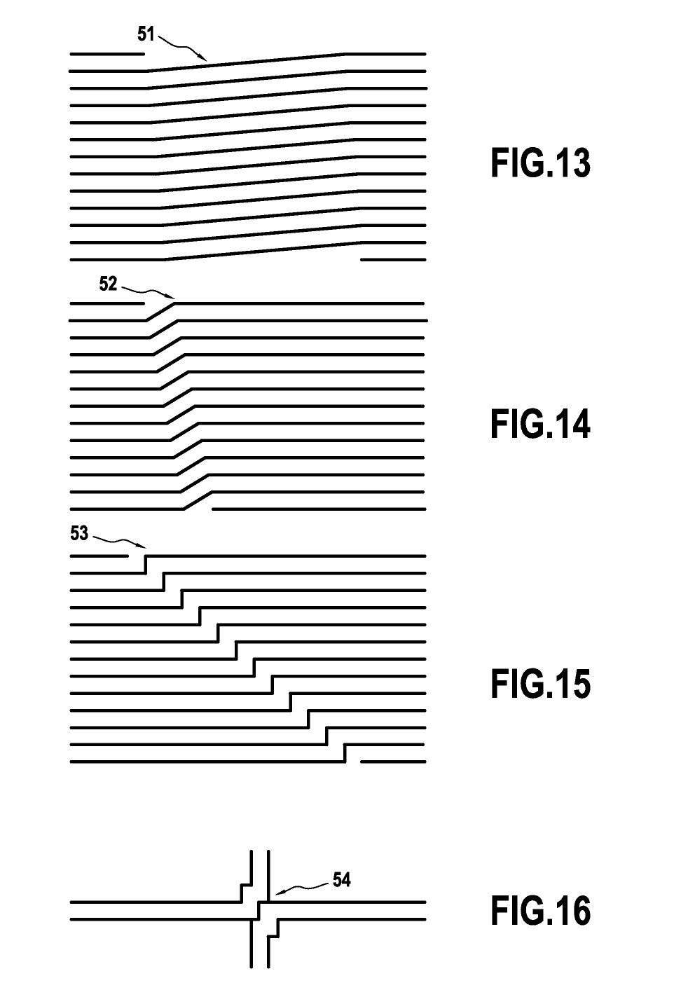

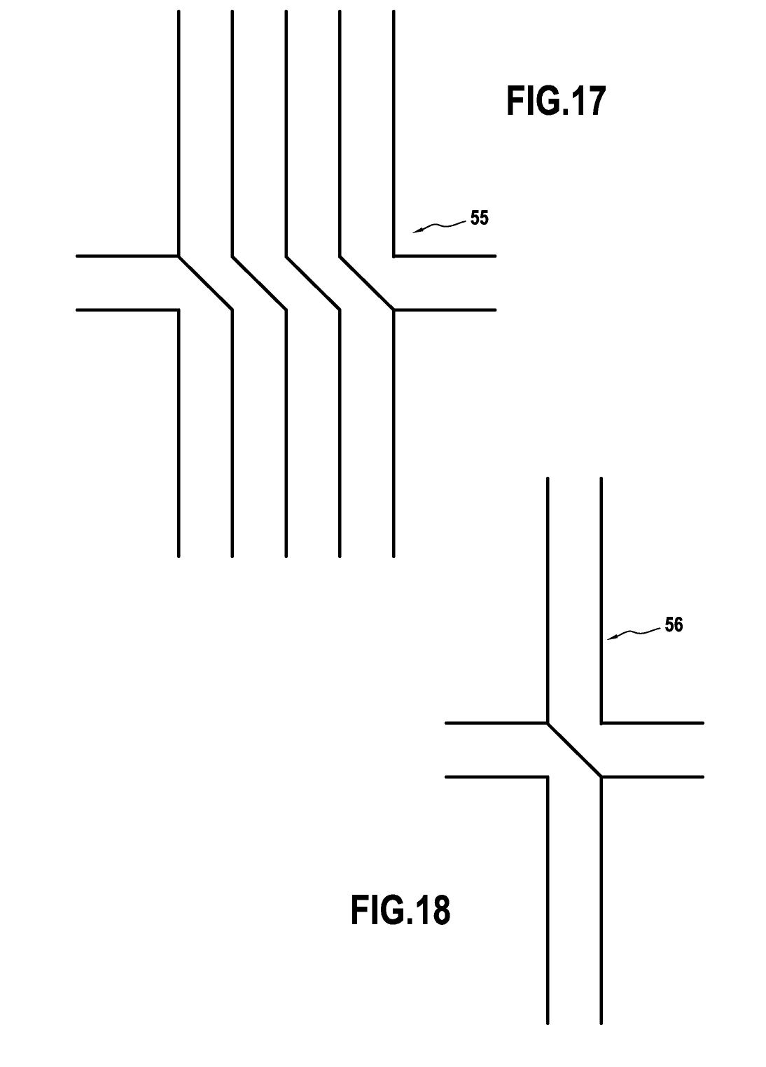

FIGS. 11 and 12 are views developed as planes showing embodiments of windings 41, 42 suitable for constituting the saddle-shaped coils 21 to 28. FIGS. 11 and 12 show concentric turns that are not connected, as they might appear during intermediate calculations when designing the coils. In practice, inter-turn transitions 51 to 56 are provided between the various turns, e.g. by applying one of the examples given in FIGS. 13 to 18.

In FIG. 13, the transitions 51 are spread, possibly over the entire length, in a configuration close to a helix.

In FIGS. 14 and 15, there are transitions 52 and 53 of the orthocyclic type.

FIGS. 16 to 18 are on a larger scale showing examples of inter-turn transitions 54 to 56 in which connection takes place on a common generator line, which may be advantageous from a mechanical point of view and for making supports. It may be observed that reduction in that the width of the conductive channel in the transition may be compensated by extra thickness on the inside.

By way of example, there follow the characteristics of a hybrid z-gradient generator device of the invention using coils 11, 12 and 14, 15 of FIGS. 1 and 1A that are fed using an IGBT technology amplifier operating at peak of 2 kV and at 625 A direct current (DC):
z gradient with Z₃=0: G_{z}=71.000 mT/m linearity:
   0.54% @ 0.1 m
   2.60% @ 0.15 m
Vector potential generating eddy currents on the outside:
A_{φ}@ 9 microtesla meters (μTm) @ 0.5 m
resistance: R=80 milliohms (mΩ)
power: P=31.328 kW
inductance: L=0.430 millihenries (mH)
switching time: Δ=0.134 milliseconds (ms).

It can thus be seen that for a nominal current value of the gradient G_{z} that is a little higher than with prior art devices, all of the other values are smaller, which represents improved linearity, a limit on induced current, smaller resistance and inductance, and a switching time that is likewise smaller, for a set of elements that themselves occupy a small amount of space, it being possible for example for the coils 11, 12 and 14, 15 to be arranged in a cylindrical annular space with an inside diameter closer to 60 centimeters (cm) and an outside diameter close to 90 cm, as can be seen in FIGS. 1 and 1A. In the same manner, in the embodiment of FIGS. 2 and 2A, the coils 111, 112, 114, and 115 may be arranged in a cylindrical annular space with an inside diameter close to 60 cm and an outside diameter close to 90 cm.

In the example given above, which corresponds to FIGS. 1 and 1A, the contributions of the coils 11, 12 and 14, 15 to the z gradient are respectively as follows:
coils 11 and 12: 58.461 mT/m
eight pairs of coils 14 and 15 placed in eight tubes 13: 12.539 mT/m.

It can be seen that in order to produce a total z gradient of 71 mT/m, although the coils 11 and 12 provide the major contribution, the set of pairs of coils 14, 15 does indeed contribute to reinforcing this gradient and to attenuating it, even though these pairs of coils 14, 15 perform a shielding function of reducing the eddy currents induced in the outer coverings.

The invention also provides a nuclear magnetic resonance imaging machine with improved gradients, comprising a tunnel 4 of axis Oz and of essentially circular section defining a volume of interest ZI, a first cylindrical annular space 1 surrounding the volume of interest ZI and containing a magnetic field gradient generator system 8 as described above for creating a magnetic field gradient in the volume of interest ZI, an outer second cylindrical annular space 2 forming a cryostat surrounding the first cylindrical annular space 1 and including a superconductive magnet device for generating a uniform magnetic field component B_{Z} along the axis Oz in the volume of interest ZI, a radio frequency emission antenna device 3 arranged inside the tunnel 4 or in the vicinity thereof in the first cylindrical annular space 1, and electrical power supply devices 6 for powering the gradient generator system 8 and the antenna device 3 (see FIG. 19).

The invention also provides a method for providing a magnetic field gradient generator system arranged in a first cylindrical annular space 1 around a tunnel 4 of axis Oz and of essentially circular section defining a volume of interest ZI in a nuclear magnetic resonance imaging machine 7 having an outer second cylindrical annular space 2 forming a cryostat surrounding the first cylindrical annular space 1 and including a superconductive magnet device for generating a uniform magnetic field component B_{Z} along the axis Oz in the volume of interest ZI in order to create a magnetic field gradient in the volume of interest ZI. This method comprises the following steps:
forming inside the first cylindrical annular space 1 solenoidal z-gradient first and second coils 11, 12 each comprising the same plurality n1 of identical turns of axis Oz and of diameter less than the outside diameter of the first cylindrical annular space 1, the turns of the second coil 12 carrying current in a direction opposite to the direction of current carried by the turns of the first coil 11 in order to produce a first z-gradient field component in an axial direction z parallel to the axis Oz;
forming a set of N1 identical non-touching first tubes 13 of axes parallel to the axis Oz and arranged in a cylindrical annular sub-space 9 situated inside the first cylindrical annular space 1 outside the z-gradient first and second coils 11, 12, each of the N1 first tubes 13 comprising solenoidal z-gradient third and fourth coils 14, 15 that are symmetrical relative to a plane xOy perpendicular to the axis Oz, each comprising the same plurality n2 of identical turns of diameter less than the inside diameter of the corresponding tube 13 and distributed in predetermined positions along the axis of this tube 13, the turns of the fourth coil 15 arranged facing the second coil 12 carrying current in a direction opposite to the direction of current carried by the turns of the second coil 12 and to the direction of current carried by the turns of the third coil 14, itself arranged facing the first coil 11 in order to produce a second z-gradient field component in the axial direction z parallel to the axis Oz;
forming a set of x-gradient fifth, sixth, seventh, and eighth coils having a saddle-shaped configuration, each having a number n3 of turns, the x-gradient fifth, sixth, seventh, and eighth coils 21, 22, 23, 24 being arranged in the vicinity of the solenoidal z-gradient first and second coils 11, 12 in positions that are radially and longitudinally symmetrical relative to the axis Oz in order to produce a first x-gradient field component in a first radial direction x of the machine perpendicular to the axis Oz;
forming a set of y-gradient ninth, tenth, eleventh, and twelfth coils 25, 26, 27, 28 having a saddle-shaped configuration, each having a number n4 of turns, the y-gradient ninth, tenth, eleventh, and twelfth coils 25, 26, 27, 28 being arranged in the vicinity of the solenoidal z-gradient first and second coils 11, 12 at positions that are radially and longitudinally symmetrical relative to the axis Oz, in superposition respectively with the x-gradient fifth, sixth, seventh, and eighth coils 21, 22, 23, 24 but offset by 90° relative thereto in order to produce a first y-gradient field component in a first radial direction y of the machine that is likewise perpendicular to the axis Oz, the first direction x being perpendicular to the second direction y; and
forming a set of N2 identical non-touching second tubes 29 of axes parallel to the axis Oz and situated in the cylindrical annular sub-space 9 situated inside the first cylindrical annular space 1 outside the z-gradient first and second coils 11, 12, being interposed between the first tubes 13, each of the N2 second tubes 29 comprising solenoidal x and y-gradient thirteenth and fourteenth coils 31, 32 that are symmetrical relative to an xOy plane perpendicular to the axis Oz, each comprising the same plurality n5 of identical turns of diameter less than the inside diameter of the corresponding tubes 29 and distributed in predetermined positions along the axis of this tube 29, the turns of the fourteenth coil 32 arranged facing the second coil 12 carrying current in a direction opposite to the direction of current carried by the turns of the second coil 12 and to the direction of current carried by the turns of the thirteenth coil 31, itself arranged facing the first coil 11, in order to produce a second field component having both an x gradient and a y gradient.

In this method, determining the characteristics of the set of solenoidal coils with the help of the regular solid spherical harmonic development of the component B_{z} of the magnetic field created in the zone of interest by each turn or turn arc of a solenoidal coil as a function of the electrical power available for powering the coils, of the outside diameter of the tunnel 4 defining the zone of interest ZI, and of the inside diameter of the outer second cylindrical annular space 2 including the superconductive magnet device.

1. A magnetic field gradient generator system arranged around a volume of interest of axis Oz in a nuclear resonance imaging machine, the system comprising at least solenoidal z-gradient first and second coils of axis Oz carrying currents in opposite directions; a set of identical z-gradient first tubes of axes parallel to the axis Oz, each comprising at least solenoidal third and fourth coils carrying currents in opposite directions and arranged in a ring outside the z-gradient first and second coils; at least x-gradient fifth to eighth coils of saddle shape and y-gradient ninth to twelfth coils of saddle shape arranged around the z-gradient first and second coils; a set of identical x and y-gradient second tubes of axes parallel to the axis Oz and situated in a ring outside the z-gradient first and second coils, being interposed between the z-gradient first tubes in the same ring, each of the x and y-gradient second tubes comprising at least solenoidal thirteenth and fourteenth coils carrying currents in opposite directions, the x and y directions being mutually orthogonal and orthogonal to the axis Oz.

2. The magnetic field gradient generator system according to claim 1, arranged in a first cylindrical annular space around a tunnel of axis Oz and of essentially circular section defining a volume of interest in a nuclear magnetic resonance imaging machine in order to create a magnetic field gradient in said volume of interest, the gradient generator system comprising, inside the first cylindrical annular space, solenoidal z-gradient first and second coils each comprising the same plurality n1 of identical turns of axis Oz and of diameter less than the outside diameter of the first cylindrical annular space, the turns of the second coil carrying current in a direction opposite to the direction of current carried by the turns of the first coil in order to produce a first z-gradient field component in an axial direction z parallel to the axis Oz; a set of N1 identical non-touching first tubes of axes parallel to the axis Oz and arranged in a cylindrical annular sub-space situated inside said first cylindrical annular space outside said z-gradient first and second coils, each of the N1 first tubes comprising solenoidal z-gradient third and fourth coils that are symmetrical relative to a plane xOy perpendicular to the axis Oz, each comprising the same plurality N2 of identical turns of diameter less than the inside diameter of the corresponding tube and distributed in predetermined positions along the axis of the tube, the turns of the fourth coil arranged facing the second coil carrying current in a direction opposite to the direction of current carried by the turns of the second coil and to the direction of current carried by the turns of the third coil, itself arranged facing the first coil in order to produce a second z-gradient field component in said axial direction z parallel to the axis Oz; a set of x-gradient fifth, sixth, seventh, and eighth coils having a saddle-shaped configuration, each having a number n3 of turns, the x-gradient fifth, sixth, seventh, and eighth coils being arranged in the vicinity of the solenoidal z-gradient first and second coils in positions that are radially and longitudinally symmetrical relative to the axis Oz in order to produce a first x-gradient field component in a first radial direction x of the machine perpendicular to the axis Ox; a set of y-gradient ninth, tenth, eleventh, and twelfth coils having a saddle-shaped configuration each having a number n4 of turns, the y-gradient ninth, tenth, eleventh, and twelfth coils being arranged in the vicinity of the solenoidal z-gradient first and second coils in positions that are radially and longitudinally symmetrical relative to the axis Oz, in superposition respectively with the x-gradient fifth, sixth, seventh, and eighth coils but offset at 90° relative to thereto in order to produce a first y-gradient field component in a second radial direction y of the machine likewise perpendicular to the axis Oz, the first direction x being perpendicular to the second direction y; a set of N2 identical non-touching second tubes parallel to the axis Oz and situated in said cylindrical annular sub-space situated inside said first cylindrical annular space outside said z-gradient first and second coils by being interposed between said first tubes, each of the N2 second tubes comprising solenoidal x and y-gradient thirteenth and fourteenth coils that are symmetrical relative to a plane xOy perpendicular to the axis Oz, each comprising the same plurality n5 of identical turns of diameter less than the inside diameter of the corresponding tube and distributed in predetermined positions along the axis of this tube, the turns of the fourteenth coil arranged facing the second coil carrying current in a direction opposite to the direction of current carried by the turns of the second coil and to the direction of current carried by the turns of the thirteenth coil, itself arranged facing the first coil in order to produce a second field component having both an x gradient and a y gradient.

3. The gradient generator system according to claim 1, wherein the solenoidal z-gradient first and second coils and the solenoidal z-gradient third and fourth coils are single-layer coils.

4. The gradient generator system according to claim 1, wherein the x-gradient fifth, sixth, seventh, and eighth coils and the y-gradient ninth, tenth, eleventh, and twelfth coils are single-layer coils, while the solenoidal x and y-gradient thirteenth and fourteenth coils are two-layer coils.

5. The gradient generator system according to claim 1, wherein the N2 second tubes are shorter than the N1 first tubes.

6. The gradient generator system according to claim 1, comprising, in the cylindrical sub-space, a ring of 12, 16, or 24 tubes made up of said second tubes alternating with said first tubes.

7. A nuclear magnetic resonance imaging machine with improved gradients, comprising a tunnel of axis Oz and of essentially circular section defining a volume of interest, a first cylindrical annular space surrounding said volume of interest and containing a magnetic field gradient generator system for creating a magnetic field gradient in said volume of interest, an outer second cylindrical annular space forming a cryostat surrounding said first cylindrical annular space and including a superconductive magnet device for generating a uniform magnetic field component B_{z} along said axis Oz in said volume of interest, a radio frequency emission antenna device arranged inside said tunnel or in the vicinity thereof in the first cylindrical annular space, and electrical power supply devices for powering the gradient generator system and the antenna device, wherein the gradient generator system is a system according to claim 1.

8. The machine according to claim 7, wherein the tunnel presents a diameter of 55 cm, the outer second cylindrical annular space presents an inside diameter of 90 cm, and said cylindrical annular sub-space presents an inside diameter of 60 cm.

9. A method of providing a magnetic field gradient system arranged around a volume of interest of axis Oz in a nuclear resonance imaging machine, the method comprising the following steps:
forming at least solenoidal z-gradient first and second coils of axis Oz carrying currents in opposite directions;
forming a set of identical z-gradient first tubes parallel to the axis Oz, each comprising at least solenoidal third and fourth coils carrying currents in opposite directions and arranged in a ring outside the z-gradient first and second coils;
forming at least x-gradient fifth to eighth coils of saddle shape arranged around the z-gradient first and second coils;
forming at least y-gradient ninth to twelfth coils of saddle shape arranged around the z-gradient first and second coils;
forming a set of identical x and y-gradient second tubes of axes parallel to the axis Oz and situated in a ring outside the z-gradient first and second coils, being interposed between the z-gradient first tubes in the same ring, each of the x and y-gradient second tubes comprising at least solenoidal thirteenth and fourteenth coils carrying currents in opposite directions, the directions x and y being mutually orthogonal and orthogonal to the axis Oz; and
determining the characteristics of all of the solenoidal coils with the help of the regular solid spherical harmonic development of the component B_{z} of the magnetic field created in the zone of interest for each turn or turn arc of a solenoidal coil as a function of the power available for electrically powering the coils, of the outside diameter of the tunnel defining the zone of interest, and of the inside diameter of an outer second cylindrical annular space including a superconductive magnet device.

10. The method according to claim 9 for providing a magnetic field gradient generator system arranged in a first cylindrical annular space around a tunnel of axis Oz and of essentially circular section defining a volume of interest in a nuclear magnetic resonance imaging machine having an outer second cylindrical annular space forming a cryostat surrounding said first cylindrical annular space and including a superconductive magnet device for generating a uniform magnetic field component B_{Z} along said axis Oz in said volume of interest in order to create a magnetic field gradient in said volume of interest, the method comprising the following steps:
forming inside said first cylindrical annular space solenoidal z-gradient first and second coils each comprising the same plurality n1 of identical turns of axis Oz and of diameter less than the outside diameter of the first cylindrical annular space, the turns of the second coil carrying current in a direction opposite to the direction of current carried by the turns of the first coil in order to produce a first z-gradient field component in an axial direction z parallel to the axis Oz;
forming a set of N1 identical non-touching first tubes of axes parallel to the axis Oz and arranged in a cylindrical annular sub-space situated inside said first cylindrical annular space outside said z-gradient first and second coils, each of the N1 first tubes comprising solenoidal z-gradient third and fourth coils that are symmetrical relative to a plane xOy perpendicular to the axis Oz, each comprising the same plurality n2 of identical turns of diameter less than the inside diameter of the corresponding tube and distributed in predetermined positions along the axis of this tube, the turns of the fourth coil arranged facing the second coil carrying current in a direction opposite to the direction of current carried by the turns of the second coil and to the direction of current carried by the turns of the third coil, itself arranged facing the first coil in order to produce a second z-gradient field component in said axial direction z parallel to the axis Oz;
forming a set of x-gradient fifth, sixth, seventh, and eighth coils having a saddle-shaped configuration, each having a number n3 of turns, the x-gradient fifth, sixth, seventh, and eighth coils being arranged in the vicinity of the solenoidal z-gradient first and second coils in positions that are radially and longitudinally symmetrical relative to the axis Oz in order to produce a first x-gradient field component in a first radial direction x of the machine perpendicular to the axis Oz;
forming a set of y-gradient ninth, tenth, eleventh, and twelfth coils having a saddle-shaped configuration, each having a number n4 of turns, the y-gradient ninth, tenth, eleventh, and twelfth coils being arranged in the vicinity of the solenoidal z-gradient first and second coils at positions that are radially and longitudinally symmetrical relative to the axis Oz, in superposition respectively with the x-gradient fifth, sixth, seventh, and eighth coils but offset by 90° relative thereto in order to produce a first y-gradient field component in a first radial direction y of the machine that is likewise perpendicular to the axis Oz, the first direction x being perpendicular to the second direction y;
forming a set of N2 identical non-touching second tubes of axes parallel to the axis Oz and situated in said cylindrical annular sub-space situated inside said first cylindrical annular space outside said z-gradient first and second coils, being interposed between said first tubes, each of the N2 second tubes comprising solenoidal x and y-gradient thirteenth and fourteenth coils that are symmetrical relative to an xOy plane perpendicular to the axis Oz, each comprising the same plurality n5 of identical turns of diameter less than the inside diameter of the corresponding tubes and distributed in predetermined positions along the axis of this tube, the turns of the fourteenth coil arranged facing the second coil carrying current in a direction opposite to the direction of current carried by the turns of the second coil and to the direction of current carried by the turns of the thirteenth coil, itself arranged facing the first coil, in order to produce a second field component having both an x gradient and a y gradient; and
determining the characteristics of the set of solenoidal coils with the help of the regular solid spherical harmonic development of the component B_{Z} of the magnetic field created in the zone of interest by each turn or turn arc of a solenoidal coil as a function of the electrical power available for powering the coils, of the outside diameter of the tunnel defining the zone of interest, and of the inside diameter of said outer second cylindrical annular space including the superconductive magnet device.
